(19) United States
(12) Patent Application Publication
(10) Pub. No.: US 2007/0026625 A1
(43) Pub. Date: Feb. 1, 2007

(54) METHOD OF FABRICATING METAL-INSULATOR-METAL CAPACITOR

(76) Inventors: Jung-Hee CHUNG, Gyeonggi-do (KR); Jong-Cheol LEE, Seoul (KR); Jae-Hyoung CHOI, Gyeonggi-do (KR); Jeong-Sik CHOI, Seoul (KR); Se-Hoon OH, Gyeonggi-do (KR); Cha-Young YOO, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/460,916

(22) Filed: Jul. 28, 2006

(30) Foreign Application Priority Data
Jul. 28, 2005 (KR) 10-2005-0069139

(51) Int. Cl. H01L 21/473

(52) U.S. Cl. 438/396; 438/785; 438/240

(57) ABSTRACT

In one embodiment, a method of fabricating a MIM capacitor includes forming an interlayer insulating layer having a contact plug on a semiconductor substrate, forming an etch stop layer on the interlayer insulating layer, and forming a mold layer having an opening exposing the contact plug on the etch stop layer. Next, a first conductive layer for the lower electrode is formed on the sidewalls and the bottom of the opening, and a photoresistive layer is formed on the first conductive layer. The mold layer and the photoresistive layer are then removed, and a composite dielectric layer is formed on the lower electrode. A second conductive layer is then formed on the composite dielectric layer. The composite dielectric layer may be composed of an oxide hafnium (HfO₂) dielectric layer and an oxide aluminum (Al₂O₃) dielectric layer, with the oxide hafnium dielectric layer having a thickness of about 20 Å to about 50 Å. The oxide aluminum dielectric layer is formed with a thickness determined by subtracting the thickness of the oxide hafnium dielectric layer from a composite dielectric layer thickness corresponding to an equivalent oxide dielectric layer thickness set to provide a predetermined capacitance of the capacitor.

### CROSS-REFERENCE TO RELATED PATENT APPLICATION

This application claims the benefit of Korean Patent Application No. 10-2005-0069139, filed on Jul. 28, 2005, in the Korean Intellectual Property Office, the disclosure of which is incorporated herein in its entirety by reference.

### BACKGROUND OF THE INVENTION

1. Field of the Invention

The present invention relates to a method of fabricating a capacitor of a semiconductor device, and more particularly, to a method of fabricating a metal-insulator-metal (MIM) capacitor using metal oxide as a dielectric layer.

2. Description of the Related Art

As the integration density of semiconductor devices is increased, capacitors in the semiconductor devices require a higher capacitance per unit area. The capacitance is inversely proportional to the distance between capacitor electrodes, and proportional to the permittivity and surface area of the electrode. Hence, in order to fabricate a capacitor having a high capacitance in a smaller area, a material having a high permittivity can be used as a dielectric layer, the thickness of the dielectric layer can be reduced, and/or the surface area of an electrode can be increased.

Methods of increasing the surface area of electrodes to increase capacitance include forming the capacitor with a flat shape, a concave shape having a recessed structure, and the like. Recently, a one cylinder stack (OCS) type of a capacitor has been proposed with a long bar shape.

Additionally, methods of reducing the thickness of a dielectric layer to increase capacitance include using metals, such as TiN, Ti, and the like, which have a high work function for an electrode, and using metal oxide made from metal having a high oxygen affinity for the dielectric layer. This is intended to suppress growth of a natural oxide layer on the metal electrode, and prevent reduction of capacitance due to the oxide layer having low permittivity. Normally, SiO₂, Si₃N₄, Si₃N₄/SiO₂(NO), and the like have been used for the dielectric layer of the capacitor. However, the dielectric layers have limits in how scaled down they can get in high integration DRAM devices. In order to overcome this problem, Al₂O₃, Ta₂O₅, Y₂O₃, HfO₂, Nb₂O₅, TiO₂, BaO, SrO, BST, and the like, which have a permittivity of 8 or higher, have been used as a typical high-k dielectric layer.

Further, a.composite dielectric layer employing two or more dielectric layers together, instead of a single high-k dielectric layer, has been proposed. This composite dielectric layer is intended to solve the problem of increased leakage current as the thickness of the dielectric layer is reduced. As opposed to the single layer, the composite dielectric layer provides the advantage of suppressing increases in leakage current while not decreasing the capacitance. This is accomplished by utilizing the characteristics of the component materials of the composite dielectric layer, such as material types, amounts of the materials, and the like. Particularly, when HfO₂ is used as a single layer, the characteristics of a semiconductor device are deteriorated due to the crystallization of HfO₂.

Examples of a typical composite dielectric layer include Ta₂O₅/TiO₂, Al₂O₃/TiO₂, Al₂O₃/HfO₂, Al₂O₃/ZrO₂, Ta₂O₅/HfO₂, Ta₂O₅/ZrO₂, and the like. In particular, a double layer or multi-layer including HfO₂ having a high permittivity of 20 through 25 has been actively studied. However, since HfO₂ has the problem of poor leakage current characteristics, and is crystallized as described above, it is limited in its use to fabricate a capacitor having excellent electrical characteristics.

### SUMMARY

Embodiments of the present invention provide a method of fabricating a metal-insulator-metal (MIM) capacitor with production advantages and improved electrical characteristics.

According to one embodiment, a method of fabricating a MIM capacitor includes forming an interlayer insulating layer having a contact plug on a semiconductor substrate, forming an etch stop layer on the interlayer insulating layer, forming a mold layer having an opening exposing the contact plug on the etch stop layer, forming a first conductive layer for a lower electrode on the sidewalls and bottom of the opening, and forming a photoresist layer on the first conductive layer. Next, the mold layer and the photoresist layer are removed after the photoresist layer has been exposed, and a composite dielectric layer is formed on the lower electrode. A second conductive layer is then formed on the composite dielectric layer. The composite dielectric layer comprises an oxide hafnium (HfO₂) dielectric layer and an oxide aluminum (Al₂O₃) dielectric layer. The oxide hafnium dielectric layer may be formed to have a thickness of about 20 Å to about 50 Å. The oxide aluminum dielectric layer is formed with a thickness determined by subtracting the thickness of the oxide hafnium dielectric layer from a composite dielectric layer thickness corresponding to an equivalent oxide dielectric layer thickness set to provide a predetermined capacitance of the capacitor.

### BRIEF DESCRIPTION OF THE DRAWINGS

The above and other features and advantages of the present invention will become more apparent by describing in detail exemplary embodiments thereof with reference to the attached drawings in which:

FIGS. 1 through 8 are cross sectional views illustrating a method of fabricating a metal-insulator-metal (MIM) capacitor according to an embodiment of the present invention;

FIG. 9 is a graph illustrating the characteristics of the MIM capacitor fabricated according to another embodiment of the present invention in accordance with a deposition order of a composite dielectric layer;

FIG. 10 is a graph illustrating the characteristics of the MTM capacitor fabricated according to yet another embodiment of the present invention in accordance with a thickness of an oxide hafnium dielectric layer; and

FIG. 11 is a graph illustrating the characteristics of the MIM capacitor fabricated according to still another embodiment of the present invention in accordance with a deposition temperature of an oxide aluminum dielectric layer.

### DETAILED DESCRIPTION

The present invention will now be described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

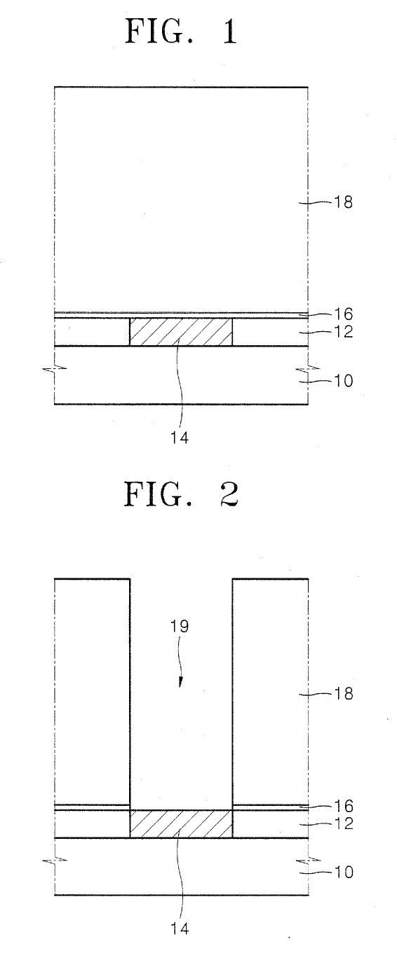

FIGS. 1 through 8 are cross-sectional views illustrating a method of fabricating a metal-insulator-metal (MIM) capacitor according to an embodiment of the present invention. In the embodiment illustrated in FIGS. 1 through 8, a one cylinder stack (OCS) capacitor is fabricated by enlarging the surface area of the capacitor to increase capacitance. In addition to the stack structure, a concave type, a flat type, and the like of a capacitor may be fabricated in accordance with conditions of desired capacitance fabrication processes.

Referring to FIG. 1, an interlayer insulating layer 12 having a contact plug 14 therein is formed on a semiconductor substrate 10. An etch stop layer 16 is formed on the interlayer insulating layer 12. The etch stop layer 16 is used as an etch stopper during etching of a mold layer 18. The mold layer 18 is formed on the etch stop layer 16. The height of the mold layer 18 is determined in accordance with the height of a lower electrode, which is formed later. The desired height of the lower electrode is determined in accordance with a desired capacitance by determining the extent that a surface of the capacitor needs to be increased.

Referring to FIG. 2, an opening 19 is formed in the mold layer 18 using a typical photolithography process in order to form a lower electrode of a MIM capacitor. More specifically, a photoresist layer (not shown) is deposited on the mold layer 18, and a region where a lower electrode of a MIM capacitor will be formed is exposed. Then, the exposed region is developed so as to form a photoresist pattern. The mold layer 18 is then etched using the photoresist pattern as an etch mask. The contact plug 14 is exposed through the opening 19 so that the contact plug 14 can be electrically connected with the later formed lower electrode. The etch method preferably uses a dry etch process. The dry etch process is performed to expose the contact plug 14 using CFx group of etch gas, for example, C₄F₆, C₃F₈.

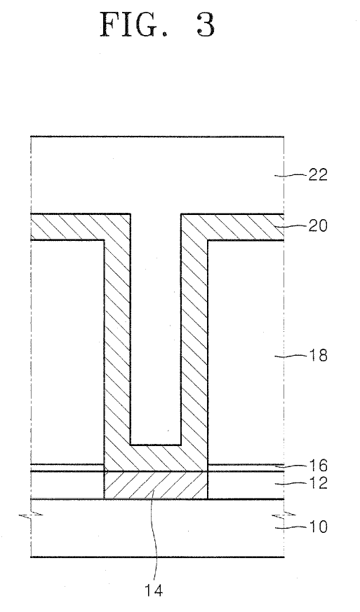

Referring to FIG. 3, a first conductive layer 20 for the lower electrode is formed on the sidewalls and bottom of the opening 19, The first conductive layer 20 for the lower electrode may be formed on the mold layer 18 in addition to the opening 19. The formation of the first conductive layer 20 on the mold layer 18 in addition to the opening 19 is preferable because of process margins. The first conductive layer 20 comprises metal, for example, Ti, TiN, Ti/TiN, TaN. The first conductive layer 20 may be formed using a method, such as atomic layer deposition (ALD), chemical vapor deposition (CVD), and metal-organic CVD (MOCVD), and the like. The first conductive layer 20 is then covered with photoresist, thereby forming a photoresist layer 22. The photoresist layer 22 is formed using semiconductor equipment such as a spin coating apparatus in relatively short time, thus reducing process time and further reducing the stress applied to the first conductive layer 20 since temperature, physical, or chemical reaction, such as deposition, is not involved. After the first conductive layer 20 for the lower electrode is formed, a dielectric layer is formed to fabricate a concave capacitor.

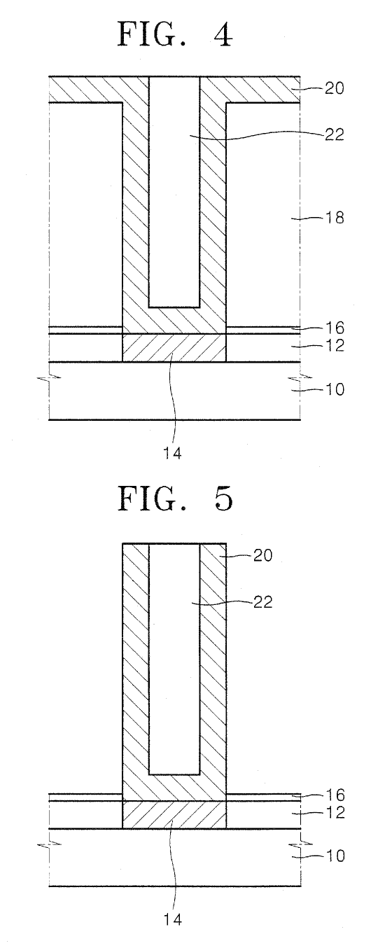

Referring to FIG. 4, the overall surface of the resultant structure is exposed and developed so as to remove the photoresist layer 22 formed on the mold layer 18 so as to expose the first conductive layer 20.

The first conductive layer 20 is then planarized to expose the upper surface of the mold layer 18, so as to separate the node. This completes the formation of the lower electrode. The planarization may be performed using an etch back process. During exposure of the photoresist layer 22, the dose of light may be controlled so that the photoresist layer 22 filled inside the opening 19 (FIG. 2) is not removed in order to protect the first conductive layer 20. Further, an etch depth may be controlled in the etch back of the first conductive layer 20 in order to maintain the desired height of the lower electrode.

Referring to FIG. 5, the mold layer 18 is removed using wet etchant, so as to expose the outer walls of the first conductive layer 20. The wet etchant for removing the mold layer 18 may use LAL etchant.

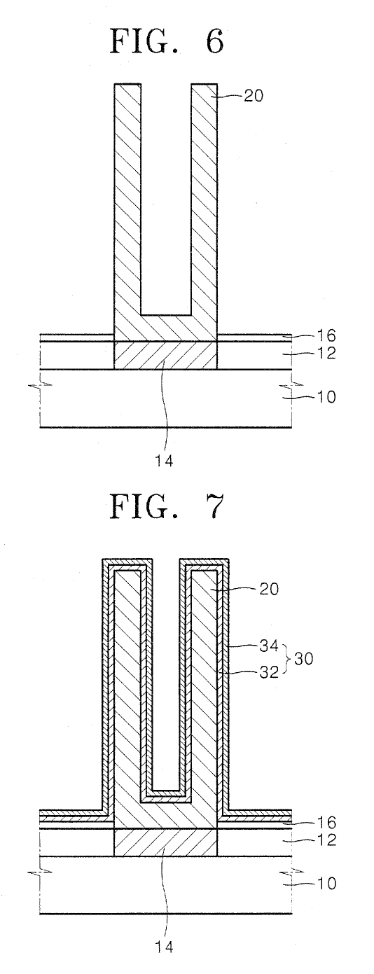

Referring to FIG. 6, the photoresist layer 22 filled inside the first conductive layer 20 is then removed by ashing and stripping processes, thereby forming the lower electrode of a MIM capacitor. The ashing process is performed by supplying reaction gas such as oxygen (O₂) and ambient gas to generate O radicals having a high reactivity so that the radical burns and removes the photoresist layer 22. The ashing process may be performed at about room temperature through a temperature of about 250° C. for about 150 seconds to about 300 seconds. After the ashing process is completed, a stripping process is performed to remove residues such as plasma atmosphere, organic materials, and the like. In the case of depositing oxide in the opening 19 (FIG. 2), and removing the oxide using a wet etch process, as etchant may penetrate between the first conductive layer and the contact plug, which may damage the lower electrode. However, if the photoresist layer 22 is removed using an ashing process according to an embodiment of the present invention, damage to the lower electrode can be prevented. The lower electrode according to the embodiment of the present invention is formed with desired height and thickness, and it is not deteriorated in its electrical characteristics as compared to the lower electrode of a conventional MIM capacitor. Therefore, the lower electrode formed by the embodiment can be usefully employed for a MIM capacitor.

Referring to FIG. 7, a composite dielectric layer 30 is formed on the first conductive layer 20. The composite dielectric layer 30 includes an oxide hafnium dielectric layer 32 and an oxide aluminum dielectric layer 34. The oxide hafnium dielectric layer 32 is formed with a thickness from about 20 Å to about 50 Å, and preferably, about 25 Å to about 45 Å. The oxide aluminum dielectric layer 34 is formed with a thickness calculated by subtracting the thickness of the oxide hafnium dielectric layer 32 from the composite dielectric layer thickness corresponding to the necessary thickness of an equivalent oxide dielectric layer to achieve a desired capacitance. Leakage current characteristics of the oxide hafnium dielectric layer 32 are not as good as those of the oxide aluminum dielectric layer 34. Hence, in order to achieve a desired equivalent oxide dielectric layer thickness, the thickness of the oxide hafnium dielectric layer 32 is set to be from about 20 Å to about 50 Å, and preferably from about 25 Å to about 45 Å. Additionally, the thickness of the oxide aluminum dielectric layer 34 is controlled so that the leakage current of the MIM capacitor will be minimized. Since the leakage current characteristic of the oxide aluminum dielectric layer is excellent with a thickness of about 15 Å or higher, the thickness of the oxide aluminum dielectric layer is not fixed to a specific value, but rather may be determined arbitrarily. The range of thicknesses for the oxide hafnium dielectric layer 32 is a result of measuring fail bit count by varying the thickness of the oxide hafnium dielectric layer 32 with respect to the same equivalent oxide dielectric layer thickness (refer to Experimental Example 2 below).

The oxide hafnium dielectric layer 32 and the oxide aluminum dielectric layer 34 may be formed by deposition using ALD, CVD, physical vapor deposition (PVD), MOCVD, and the like. Preferably, a hafnium source of the oxide hafnium dielectric layer 32 uses an organic metal precursor, such as HfCl₄, Hf(OtBu)₄, Hf(MMP)₄, Hf(Net₂)₄, Hf(NMe₂)₄, and an oxygen source thereof uses O₃. The oxide hafnium dielectric layer 32 is formed by deposition at a temperature of about 250° C. through about 300° C. using an ALD method. The aluminum source of the oxide aluminum dielectric layer 34 uses an organic metal precursor, such as (CH₃)₃Al(TMA), AlCl₃, AlH₃N(CH₃)₃, C₆H₁₅AlO, (C₄H₉)₂AlCl, (C₂H₅)₃Al, (C₄H₉)₃Al, and an oxygen source thereof uses O₃. The oxide aluminum dielectric layer 34 is formed by deposition at a temperature of about 400° C. through about 460° C., and preferably at about 450° C., using, preferably, an ALD method. The ALD method allows a low temperature deposition, and provides excellent step coverage. The deposition of the oxide aluminum dielectric layer 34 at the above temperatures provides the effect of curing the oxide hafnium dielectric layer 32, which is previously formed, and can help minimize the leakage current of the MIM capacitor.

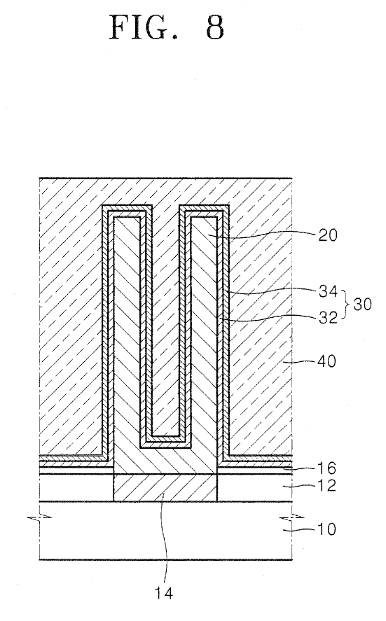

Referring to FIG. 8, second conductive layer 40 is formed on the oxide aluminum dielectric layer 34, The second conductive layer 40 is formed as the upper electrode of the capacitor and is composed of a metal like the first conductive layer 20, preferably of Ti, TiN, Ti/TiN, TaN, and the like. Further, the second conductive layer 40 may be formed using a method such as CVD, MOCVD, and the like. Therefore, according to this embodiment, the fabrication processes can be performed more easily using photoresist, and the electrical characteristics of the MIM capacitor can be further improved by forming the composite dielectric layer 30 with the oxide hafnium dielectric layer 32 having a thickness from about 20 Å to about 50 Å, and preferably from about 25 Å to about 45 Å.

Hereinafter, experimental examples performed to determine process parameters in a method of fabricating a MIM capacitor according to an embodiment of the present invention will be explained. However, specific values, which will be described in the examples, may be varied in accordance with an equivalent oxide thickness of a desired dielectric layer of the MIM capacitor according to an embodiment of the present invention, a capacitance of a capacitor, and the like.

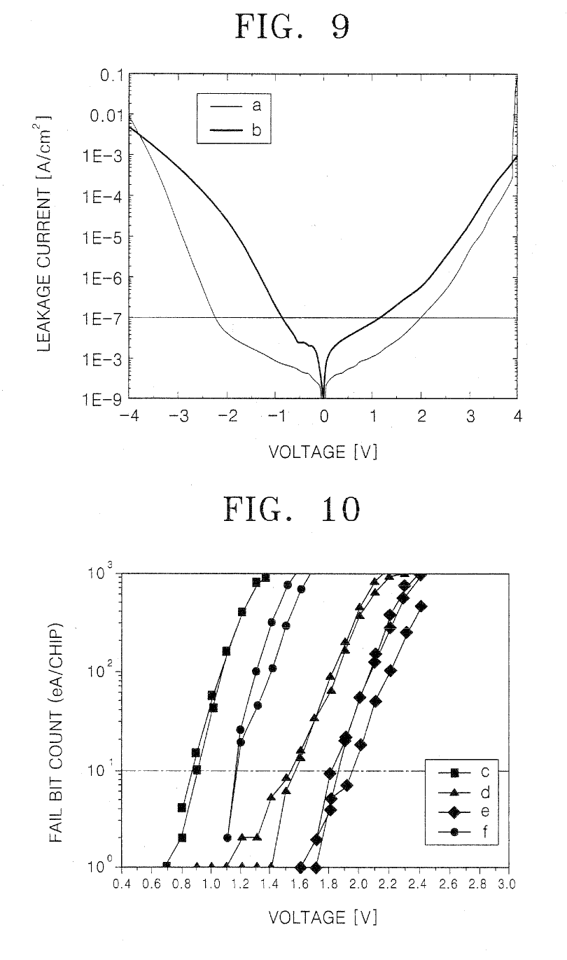

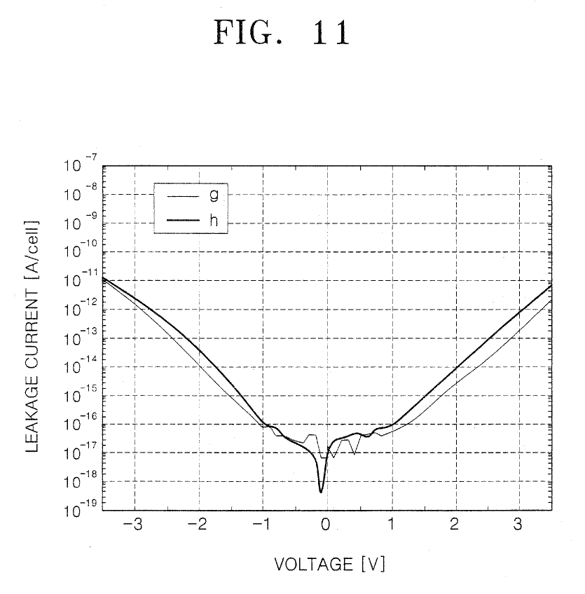

FIG. 9 is a graph illustrating the characteristics of the MIM capacitor fabricated according to an embodiment of the present invention in accordance with a deposition order of a composite dielectric layer. FIG. 10 is a graph illustrating the characteristics of the MIM capacitor fabricated according to an embodiment of the present invention in accordance with a thickness of an oxide hafnium dielectric layer. FIG. 11 is a graph illustrating the characteristics of the MIM capacitor fabricated according to an embodiment of the present invention in accordance with a deposition temperature of an oxide aluminum dielectric layer.

### EXPERIMENTAL EXAMPLE 1

In order to examine the characteristics of the capacitor fabricated according to an embodiment of the present invention, in which an oxide hafnium dielectric layer and an oxide aluminum dielectric layer is formed, the leakage current characteristics of the MIM capacitor in accordance with the order formation of the dielectric layers is evaluated.

In the fabrication of the MIM capacitor according to this example, a 20 Å thick oxide hafnium dielectric layer is formed on a TiN lower electrode, a 40 Å thick oxide aluminum dielectric layer is formed on the oxide hafnium dielectric layer, and an upper electrode composed of TiN is formed on the resulting structure. The upper and lower electrodes are formed at a temperature of about 560° C. using an ALD method. The dielectric layers are deposited at a temperature of about 350° C. using an ALD method, in which O₃ is used as an oxygen source gas. In a comparative example, upper and lower electrodes can be formed in the same manner as the above example, but the oxide hafnium dielectric layer is formed after the oxide aluminum dielectric layer.

The results of measuring the leakage current amount in the unit area of the semiconductor substrate in accordance with voltages applied to the capacitor are illustrated in FIG. 9. In FIG. 9, the MIM capacitor of the present invention is indicated as ‘a’, and that of the comparative example is indicated as ‘b’. As shown in FIG. 9, the MIM capacitor according to an embodiment of the present invention shows much lower leakage currents for most of the voltage values as compared to those of the comparative example. In particular, in the condition where an applied voltage is about 1.2 V, the usual commercialized standard of a capacitor, the MIM capacitor of the present invention shows a significantly better leakage current characteristic than that of the comparative example.

The reason of poor leakage current characteristic in the comparative example is that the oxide aluminum dielectric layer reacts with the TiN conductive material of the lower electrode at their interface, thereby causing defects in the MIM capacitor. Further, the oxide hafnium dielectric also reacts with TiCl₄ generated after the oxide aluminum dielectric layer is formed to generate HfCl₄, thereby deteriorating the characteristic as a dielectric layer.

### EXPERIMENTAL EXAMPLE 2

In this example, a MIM capacitor was fabricated by varying the thickness of an oxide hafnium dielectric layer in a same range of an equivalent oxide dielectric layer thickness and the leakage current characteristic of the MIM capacitor was evaluated.

The MIM capacitor of the present invention was fabricated in the same manner as that of the experiment example 1, in which an oxide hafnium dielectric layer of the MIM capacitor was formed with thicknesses of 20 Å, 40 Å, 45 Å, and 50 Å, respectively. An equivalent oxide dielectric layer thickness of 20 Å was used in order to compare the leakage current characteristics of the capacitor in a same range of an equivalent oxide dielectric layer thickness. Therefore, an oxide aluminum dielectric layer was formed with thicknesses of 32 Å, 24 Å, 22 Å, and 20 Å, respectively, which were achieved by subtracting a thickness of the oxide hafnium dielectric layer from the composite dielectric layer thickness corresponding to an equivalent oxide dielectric layer thickness. A voltage was applied to the capacitors to evaluate the electrical characteristics of the capacitors where the fail bit counts in one chip are measured, and the number of the capacitors with high leakage currents are represented by the black dots.

In FIG. 10, the MIM capacitor having a 20 Å thickness of the oxide hafnium dielectric layer was indicated as ‘c’, the MIM capacitor having a 40 Å thickness thereof was indicated as ‘d’, the MIM capacitor having a 45 Å thickness thereof was indicated as ‘e’, and the MIM capacitor having a 50 Å thickness thereof was indicated as ‘f’.

Referring to FIG. 10, as the voltage applied to the MIM capacitor was increased, the fail bit counts were increased. MIM capacitors showing 10 fail bits or more at 1.2 V, cannot be used. In FIG. 10, the capacitor represented by ‘c’ showed about 1000 fail bits, and the capacitor represented by ‘d’ showed about 20 through 30 fail bits. However, the capacitors represented by ‘e’ and ‘f’ showed fail bits below 5. Hence, it was acknowledged that the ‘e’ and ‘f’ capacitors were usable as a MIM capacitor. However, in the method of fabricating a capacitor according to an embodiment of the present invention, the oxide hafnium dielectric layer can be formed with a thickness of about 20 Å to about 50 Å, and preferably in a range of about 25 Å through about 45 Å. Since the oxide aluminum dielectric layer showed excellent leakage current characteristic in the thickness of about 15 Å or higher, the leakage current characteristic was less influenced by the oxide aluminum dielectric layer than the oxide hafnium dielectric layer. Thus, in this example, the thickness of the oxide hafnium dielectric layer varied, and the thickness of the oxide aluminum dielectric layer was adjusted in a range of about 15 Å or higher in order to form a desired equivalent oxide dielectric layer thickness.

### EXPERIMENTAL EXAMPLE 3

An oxide aluminum dielectric layer was deposited on an oxide hafnium dielectric layer, and the leakage current characteristics of a MIM capacitor were evaluated in accordance with the deposition temperature.

The MIM capacitor of the present invention was fabricated in the same manner as with experimental example 1, but the deposition temperature of the oxide aluminum dielectric layer was set to vary between about 300° C. and about 450° C.

Results of measuring a leakage current amount per cell of the semiconductor substrate in accordance with voltages applied to the capacitor are illustrated in FIG. 11. The deposition temperature of the capacitor represented by ‘g’ was set to about 450° C., and a deposition temperature of the capacitor represented by ‘h’ was set to about 300° C. In FIG. 11, it was acknowledged that the capacitor of ‘g’ showed less leakage current than the capacitor of ‘h’ at about 1.2 V. Hence, the leakage current of the MIM capacitor of the present invention was decreased where the oxide aluminum dielectric layer was deposited at a temperature of 450° C. so that the electrical characteristic of the capacitor could be maximized. Further, the MIM capacitor of the present invention showed a curing effect of the oxide hafnium dielectric layer formed below the oxide aluminum dielectric layer. As a process of curing the oxide hafnium dielectric layer was performed at a temperature of about 450° C., the process of curing the oxide hafnium dielectric layer could be performed together with the process of depositing the oxide aluminum dielectric layer without the need of a separate curing process. Hence, the method of fabricating the MIM capacitor according to an embodiment of the present invention had an advantage in production procedures.

According to an embodiment of the present invention, the use of a photoresist layer covering the conductive layer used in forming a cylinder-shaped lower electrode provides advantages of improved procedure time, and lower production costs during the processes of fabricating a capacitor. Further, as the photoresist is removed using ashing and stripping processes, damage to the lower electrode can be prevented, thereby contributing to an improved production yield and better reliability of the semiconductor devices. Further, according to an embodiment of the present invention, the oxide hafnium dielectric layer is formed on the lower electrode to have a thickness of about 20 Å to about 50 Å, and preferably from about 25 Å to about 45 Å. The oxide aluminum dielectric layer is then formed on the oxide hafnium dielectric layer by deposition at a temperature of about 450° C. through about 500° C., thereby improving the leakage current characteristics of a MIM capacitor. Therefore, according to an embodiment of the present invention, there is provided a method of fabricating a MIM capacitor by simplifying fabrication processes, and with a resulting capacitor with improved leakage current characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a metal-insulator-metal (MIM) capacitor comprising:
forming an interlayer insulating layer on a semiconductor substrate, the interlayer insulating layer having a contact plug;
forming an etch stop layer on the interlayer insulating layer;
forming a mold layer on the etch stop layer, the mold layer having an opening exposing the contact plug;
forming a first conductive layer on a sidewall and a bottom of the opening;
forming a photoresist layer on the first conductive layer;
processing the photoresist and first conductive layers to form a lower electrode node;
removing the mold layer and the photoresist layer;
forming a composite dielectric layer on the lower electrode, the composite dielectric layer including an oxide hafnium (HfO₂) dielectric layer having a thickness of about 20 Å to about 50 Å, and an oxide aluminum dielectric layer formed on the oxide hafnium dielectric layer, wherein a thickness of the oxide aluminum dielectric layer is determined by subtracting the thickness of the oxide hafnium dielectric layer from a composite dielectric layer thickness corresponding to an equivalent oxide dielectric layer thickness set to provide a predetermined capacitance; and
forming a second conductive layer on the composite dielectric layer.

2. The method according to claim 1, wherein the oxide hafnium dielectric layer is formed with a thickness of about 25 Å to about 45 Å.

3. The method according to claim 1, wherein the oxide aluminum dielectric layer is formed with a thickness of at least about 15 Å.

4. The method according to claim 1, wherein processing the photoresist and first conductive layers comprise:
exposing the surface of the photoresistive layer and developing the exposed photoresistive layer so as to expose the first conductive layer; and
planarizing the first conductive layer to expose the mold layer to form the separate lower electrode node.

5. The method according to claim 4, wherein planarizing the first conductive layer comprises using one selected from the group consisting of chemical mechanical polishing (CMP) and etch back processes.

6. The method according to claim 4, wherein exposing the surface of the photoresistive layer comprises controlling a dose of a light during the exposure such that the photoresistive layer is exposed except for the portion of the photoresistive layer inside of the opening.

7. The method according to claim 1, wherein removing the mold layer comprises using a wet etch process.

8. The method according to claim 7, wherein the first conductive layer and the second conductive layer include at least one of Ti, TiN, Ti/TiN, and TaN.

9. The method according to claim 1, wherein the composite dielectric layer is formed using at least one of atomic layer deposition (ALD), chemical vapor deposition (CVD), physical vapor deposition (PVD), and metal-organic CVD (MOCVD).

10. The method according to claim 9, wherein the oxide hafnium dielectric layer uses an organic metal precursor chosen from HfCl₄, Hf(OtBu)₄, Hf(MMP)₄, Hf(Net₂)₄, and Hf(NMe₂)₄ for a hafnium source, uses O₃ for an oxygen source, and is deposited using ALD.

11. The method according to claim 10, wherein the oxide hafnium dielectric layer is formed at a temperature ranging from about 250° C. to about 300° C.

12. The method according to claim 9, wherein the oxide aluminum dielectric layer uses an organic metal precursor chosen from (CH₃)₃Al(TMA), AlCl₃, AlH₃N(CH₃)₃, C₆H₁₅AlO (C₄H₉)₂AlCl, (C₂H₅)₃Al, and (C₄H₉)₃Al for an aluminum source, uses O₃ for an oxygen source, and is deposited using ALD.

13. The method according to claim 12, wherein the oxide aluminum dielectric layer is formed at a temperature ranging from about 400° C. to about 460° C.

14. The method according to claim 13, wherein the oxide aluminum dielectric layer is formed at a temperature ranging from about 440° C. to about 460° C.

15. A method of manufacturing a semiconductor capacitor comprising:
forming a first conductive layer over a semiconductor substrate;
forming an oxide hafnium (HfO₂) dielectric layer on the first conductive layer, the oxide hafnium dielectric layer having a thickness of about 20 Å to about 50 Å;
forming an oxide aluminum dielectric layer on the oxide hafnium dielectric layer, the oxide aluminum dielectric layer having a thickness of at least about 15 Å; and
forming a second conductive layer on the oxide aluminum dielectric layer,
wherein the thickness of the oxide aluminum dielectric layer is determined by subtracting the thickness of the oxide hafnium dielectric layer from a composite dielectric layer thickness corresponding to an equivalent oxide dielectric layer thickness set to provide a predetermined capacitance.

16. The method of claim 15, further comprising:
forming an interlayer insulating layer on the semiconductor substrate;
forming a contact plug in the interlayer insulating layer;
forming an etch stop layer on the interlayer insulating layer and the contact plug;
forming a mold layer on the etch stop layer;
forming an opening by etching the mold layer to the etch stop layer and removing the etch stop layer to expose the contact plug; and
forming the first conductive layer on the mold layer and contact plug, wherein the first conductive layer is also formed on a sidewall and bottom of the opening.

17. The method of claim 16, further comprising:
forming a photoresist layer on the first conductive layer before the oxide hafnium dielectric layer is formed;
exposing the surface of the photoresist layer such that the photoresist layer is exposed except for the portion of the photoresist layer inside of the opening and developing the exposed photoresist layer to expose the first conductive film;
planarizing the first conductive layer to expose the mold layer; and
removing the mold layer and the photoresist layer.

18. The method of claim 17, wherein the mold layer is removed by a wet etching process and the photoresist layer is removed using an ashing and stripping process.

19. The method of claim 15, wherein the capacitor is formed in a one cylinder stack configuration.
